(19) United States
(12) Patent Application Publication
(10) Pub. No.: US 2014/0002156 A1
(43) Pub. Date: Jan. 2, 2014

(54) DUTY CYCLE CORRECTION WITHIN AN INTEGRATED CIRCUIT

(71) Applicants: Sandeep Dwivedi, Bangalore (IN); Muniswara Reddy Vorugu, Chittoor (IN); Nidhir Kumar, Bangalore (IN)

(72) Inventors: Sandeep Dwivedi, Bangalore (IN); Muniswara Reddy Vorugu, Chittoor (IN); Nidhir Kumar, Bangalore (IN)

(73) Assignee: ARM LIMITED, Cambridge (GB)

(21) Appl. No.: 13/534,274

(22) Filed: Jun. 27, 2012

(51) Int. Cl. H03K 3/017

(52) U.S. Cl. 327/175

(57) ABSTRACT

An integrated circuit 2 operates using a digital signal having a duty cycle. Duty cycle correction circuitry 26, 28, 30 operate under control of digital correction values which adjust the duty cycle of the digital signal to a target duty cycle. Periodically, detection of the duty cycle output from the duty cycle correction circuitry 26, 28, 30 is performed to determine whether or not this has drifted outside of a threshold range of duty cycles and if necessary the digital correction value is changed to bring the duty cycle back within the threshold range. The duty cycle correction circuitry 26, 28, 30 employs common mode logic stages 44, 46 and an auxiliary current path 48 which is controlled in its impedance by the digital correction value. The auxiliary current path 48 applies an offset voltage within the common mode logic stage 44 which adjusts the duty cycle of the digital signal represented by the differential signals propagating through the common mode logic stage 44.

### BACKGROUND OF THE INVENTION

1. Field of the Invention

This invention relates to the field of integrated circuits. More particularly, this invention relates to the correction of the duty cycle of a digital signal within an integrated circuit.

2. Description of the Prior Art

Integrated circuits typically operate using many digital signals. Examples of such signals include clock signals which are used to regulate and control the processing operations of an integrated circuit. The clock signals typically have the form of a square wave. An ideal square wave will typically have a duty cycle of 50% corresponding to the signal having an equal durations for its high periods and its low periods. The edges in the signal when it transitions from low to high and from high to low are often used as timing points for controlling the operation of the integrated circuit. If the duty cycle varies from the 50% duty cycle, then this can cause difficulty in the operation of the integrated circuit. As an example, double data rate (DDR) memory circuits take timing information from both the rising edge and the falling edge of their signals and the tolerances required in the duty cycle of the clock signal are narrow, e.g. plus or minus 3%.

It is known to provide duty cycle correction mechanism within integrated circuits. Analog duty correction cycle circuits may operate continuously to monitor the duty cycle and hold this within a desired range. Such circuits have a number of disadvantages, such as a finite settle time upon every start up during which the integrated circuit may not be released to operate correctly and the continuous consumption of power during operation of the integrated circuit by the analog duty cycle correction circuitry. Another approach is to use digitally controlled duty cycle correction circuitry in which upon start up the degree of correction required is measured and then a digital control value is set corresponding to this required correction for use during continued operation of the integrated circuit. The digital correction circuitry may then be powered down during normal operation.

### SUMMARY OF THE INVENTION

Viewed from one aspect the present invention provides an integrated circuit operating with a digital signal having a duty cycle, said apparatus comprising:

duty cycle correcting circuitry configured to be controlled with a digital correction value to correct said duty cycle to match a target duty cycle;

detecting circuitry configured periodically to detect if said duty cycle has drifted outside of a threshold range of duty cycles encompassing said target duty cycle; and

controller circuitry coupled to said duty cycle correcting circuitry and to said detecting circuitry and configured to change said digital correction value so as to control said duty cycle correcting circuitry to bring said duty cycle back within said threshold range if said detecting circuitry detects that said duty cycle has drifted outside of said threshold range.

The present invention provides the ability for duty cycle correcting circuitry controlled by a digital correction value to be used to track and correct for the drift in the duty cycle of a digital signal that can occur during operation, e.g. due to changes in temperature and/or voltage. Thus, the variations in manufacture of an individual integrated circuit which result in duty cycle variation can be corrected at start up and then other time-varying variations can be corrected with the periodic detection of whether the duty cycle has drifted outside of a threshold range and the corresponding adjustment of the digital correction value to bring the duty cycle back within the threshold range.

The digital correction value may be stored within a register. Thus, when the integrated circuit starts its operation, the value stored within that register may be read and used to control the duty cycle without a calibration process being required thereby reducing the settle time associated with duty cycle correction. Upon the first use of the integrated circuit a default value may be used within this register and a longer first use settle time may be tolerated. The digital correction value may be stored into the register upon first operation and/or upon a reset to the duty cycle correcting circuitry.

It will be appreciated that the digital signal which has its duty cycle corrected may have a variety of uses within the integrated circuit. One form of digital signal which it may be desired to control with the present techniques is a clock signal for controlling operation of the integrated circuit. This may be particularly the case when the integrated circuit is one of a memory controller for double data rate memory or a double data rate memory itself.

The duty cycle correcting circuitry may include a common mode logic stage in which the digital signal is represented as a difference between two signals propagating through the common mode logic stage. Such common mode logic stages are well suited to high speed operation and noise resistant operation.

The duty cycle correcting circuitry in some embodiments may be controlled by the digital correction value to generate an asymmetry in operation of the common mode logic stage with respect to different phases of the digital signal. Thus, the common mode logic stage may have one operational parameter in relation to a rising edge of the digital signal and a different operational parameter in relation to the falling edge of that signal. This asymmetry in operation can be used to correct/adjust the duty cycle between the digital signal received by the common mode logic stage and the digital signal output from the common mode logic stage.

In some embodiments this asymmetry may be provided by an arrangement in which the common mode logic stage comprises a first current path coupled to a first signal node and switched to a low impedance state when the digital signal is within a first phase and a second current path coupled to a second signal node and switched to a low impedance state when the digital signal is within a second phase; and the duty cycle correcting circuitry comprises an auxiliary current path coupled to a selected one the said first signal node and the second signal node, impedance of the auxiliary current path being controlled by the digital correction value to provide an offset to a voltage level at the selected one of the first signal node and the second signal node.

Such an arrangement permits the noise and jitter resistant operation of a common mode logic stage to be combined with duty cycle correction under control of a digital correction value giving the advantages of rapid start up and low power during normal operation.

In some embodiments, one bit of the digital correction value may be used to control the digital cycle correction circuitry to select which of the first signal node and the second signal node to correct to the auxiliary current path. Thus, only one side of the common mode logic stage is subject to influence by the auxiliary current path, but this is sufficient to adjust the overall duty cycle of the signal passing through the common mode logic stage as the digital signal is represented by the difference between the signals on each of the sides of the common mode logic stage.

The auxiliary signal path may have a variety of different forms. In one form it comprises a plurality of transistors connected in parallel and each controlled to switch between a high impedance state and a low impedance state by a respective bit of the digital correction value.

The effective range of the adjustment which may be applied by the auxiliary signal path may be improved in embodiments in which the magnitude of the low impedance state of the different parallel connected transistors have a binary relation with respect to each other so that a binary value of the digital correction value can select a corresponding magnitude combined impedance from the plurality of parallel transistors.

In some embodiments a further common mode logic stage is disposed downstream of the common mode logic stage having the auxiliary current path. The further common mode logic stage can have a greater tail current impedance than the common mode logic stage which applies the duty cycle correction. This greater tail current impedance is better suited to the further processing of the digital signal, such as by a differential-to-single converter stage which may be disposed to receive the digital signal from the further common mode logic stage.

The integrated circuit may include a plurality of duty cycle correcting circuitry, each configured to correct the duty cycle of a respective digital signal at a different point within the integrated circuit. These may be different digital signals, or the same digital signal but at different points along its propagation path. This plurality of duty cycle correcting circuitry may be connected via multiplexing circuitry to shared detecting circuitry and shared controller circuitry. This helps reduce the circuit overhead associated with duty cycle correction.

The detecting circuitry can have a variety of different forms. In some embodiments the detecting circuitry comprises averaging circuitry configured to generate an average value indicative of the duty cycle and comparator circuitry configured to compare this average value with a predetermined value indicative of a given duty cycle and to generate a comparison output value indicating whether the duty cycle is greater than or less than a given duty cycle. Such a comparison value can be used by the controller, (e.g in the form of a finite state machine) to control a process for determining what digital correction values should be applied in order to achieve a target duty cycle.

In some embodiments the detecting circuitry may be configured to detect if the duty cycle is outside of the threshold range of duty cycles by comparing an average value, determined by the averaging circuitry, with predetermined values corresponding to limiting values of the threshold range of duty cycles. Thus, if the average value corresponds to a duty cycle outside of the threshold range, the comparator circuitry will indicate this and corrective action upon the digital correction value may be taken.

It will be appreciated that while the threshold range of duty cycles can have a variety of spans, a practical and effective span is one in which the threshold range of duty cycles extends from 49% to 51% for a target duty cycle of 50%.

Another situation in which the present techniques can be used is to control the duty ratio of a data signal used in access to a memory, e.g. DQ and DQS signals for DDR memory interface circuitry.

Viewed from another aspect the present invention provides an integrated circuit operating with a digital signal having a duty cycle, said apparatus comprising:

duty cycle correcting means for correcting said duty cycle to match a target duty cycle under control of a digital correction value;

detecting means for periodically detecting if said duty cycle has drifted outside of a threshold range of duty cycles encompassing said target duty cycle; and

controller means, coupled to said duty cycle correcting means and to said detecting means, for changing said digital correction value so as to control said duty cycle correcting means to bring said duty cycle back within said threshold range if said detecting means detects that said duty cycle has drifted outside of said threshold range.

Viewed from a further aspect the present invention provides a method of correcting a duty cycle of a digital signal within an integrated circuit, said method comprising the steps of:

correcting said duty cycle to match a target duty cycle duty cycle under control of a digital correction value;

periodically detecting if said duty cycle has drifted outside of a threshold range of duty cycles encompassing said target duty cycle; and

if said duty cycle has drifted outside of said threshold range, then changing said digital correction value so as to control bringing of said duty cycle back within said threshold range.

The above, and other objects, features and advantages of this invention will be apparent from the following detailed description of illustrative embodiments which is to be read in connection with the accompanying drawings.

### BRIEF DESCRIPTION OF THE DRAWINGS

FIG. 1 schematically illustrates an integrated circuit incorporating duty cycle correction circuitry;

FIG. 2 schematically illustrates distribution of a clock signal within an integrated circuit;

FIG. 3 schematically illustrates duty cycle correction at multiple points within an integrated circuit using a digital correction value;

FIG. 4 schematically illustrates duty cycle correction circuitry based upon common mode logic;

FIG. 5 is a signal diagram illustrating the operation of the circuitry of FIG. 4;

FIG. 6 is a flow diagram schematically illustrating the initial setting of a digital correction value;

FIG. 7 is a flow diagram schematically illustrating the periodic detection of whether or not a duty cycle has drifted outside of a threshold range of duty cycles; and

FIG. 8 schematically illustrates the use of duty cycle correction for the data path within memory interface circuitry.

### DESCRIPTION OF THE EMBODIMENTS

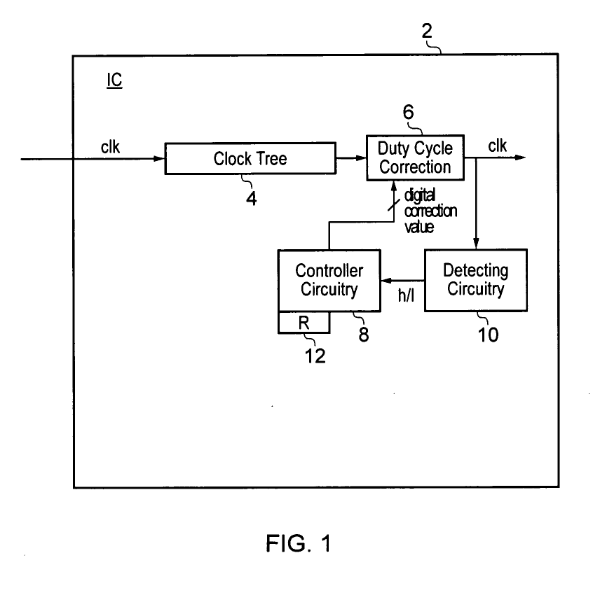

FIG. 1 schematically illustrates an integrated circuit 2 operating with a digital signal in the form of a clock signal clk that is distributed by clock tree circuitry 4. In order to correct the duty cycle of the clock signal clk to a target duty cycle (e.g. 50%), there is provided duty cycle correction circuitry 6 which receives a duty cycle uncorrected clock signal and outputs a duty cycle corrected clock signal. The duty cycle correction circuitry 6 operates under control of a digital correction value which sets the magnitude and direction of the duty cycle correction applied by the duty cycle correction circuitry 6. This digital correction value is generated by controller circuitry 8. The controller circuitry 8 determines what magnitude the digital correction value should have in response to indications provided to it by detecting circuitry 10 which also measures whether the clock signal output from the duty cycle correction circuitry 6 has a duty cycle which is higher or lower than a target duty cycle. The duty cycle correction circuitry 6, the detecting circuitry 10 and the controller circuitry 8 may be considered to form a feedback arrangement in which the degree of duty cycle correction applied by the duty cycle correction circuitry 6 is adjusted until a desired target duty cycle is achieved.

This feedback operation and the setting of the digital correction value needed to correct for manufacturing process variations within the integrated circuit 2 may be performed upon the initial first operation of the integrated circuit 2. It may also be performed whenever the duty cycle correction circuitry 6 and/or the controller circuitry 8 is reset. Once the digital correction value to be applied has been determined, it may be stored within a register 12 of the controller circuitry 8. This stored digital correction value is then available for rapid use without needing to be recalibrated when the integrated circuit 2 is switched on at a later time. This helps reduce the settle time needed for the clock signal to achieve the desired duty cycle.

As well as operating so as to set the digital correction value when the integrated circuit 2 is started, the controller circuitry 8 operates to initiate periodic checks to determine whether the duty cycle of the clock signal output by the duty cycle correction circuitry 6 has drifted outside of a threshold range of duty cycle. For example, if the target duty cycle is 50%, then the detection circuitry 10 may periodically detect whether the duty cycle being output by the duty cycle correction circuitry 6 has drifted outside of a range of 49% to 51%. If the duty cycle is still within this threshold range, then no corrective action need be taken. However, if the duty cycle if outside of this threshold range, then the digital correction value may be adjusted to bring the duty cycle back within the threshold range. Drifts in the duty cycle of the clock signal output from the duty cycle correction circuitry 6 may, for example, be the result of temperature changes within the integrated circuit 2 and/or changes in the operational voltage of the integrated circuit 2. Other effects causing drift may be, for example, the ageing or wearout of the integrated circuit 2 and/or mechanical stress upon the integrated circuit 2.

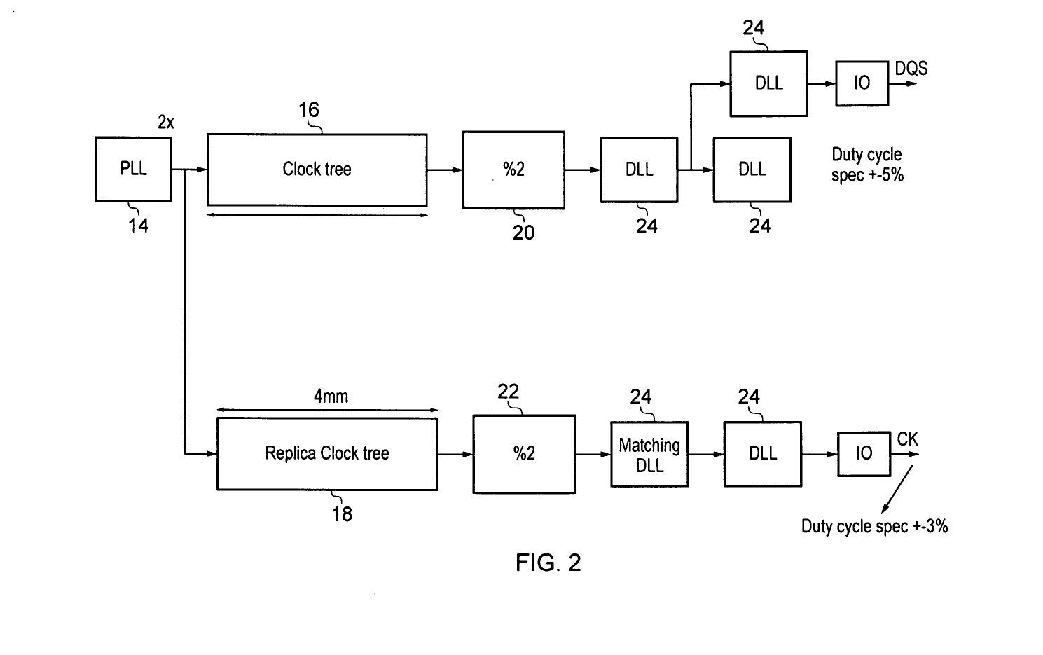

FIG. 2 schematically illustrates clock signal distribution within a double data rate memory system. In this example, the phase lock loop 14 runs at twice the desired data rate and is distributed through physically large clock trees 16, 18 at this high rate. Before being output from the integrated circuit, the clock signal is divided by two in data rate using dividers 20, 22. Such division of the clock signal by two is used to remove duty cycle distortions introduced within the clock trees 16, 18, but has the penalty that the clock signal distributed within the clock trees 16, 18 must have twice the eventual desired clock rate (this results in increased power consumption and increased design difficulty). Before being output from the integrated circuit or used within the integrated circuit elsewhere the divided clock signal is passed through various delay lock loop elements 24. These can reintroduce noise and jitter.

The present techniques may use similar clock tree distribution, but do not need to operate on a clock signal which is twice the frequency of the eventually desired clock signal. Instead, duty cycle correction circuitry may be employed that is capable of operating on the clock signal of the base frequency rather than requiring a clock signal of a multiple frequency.

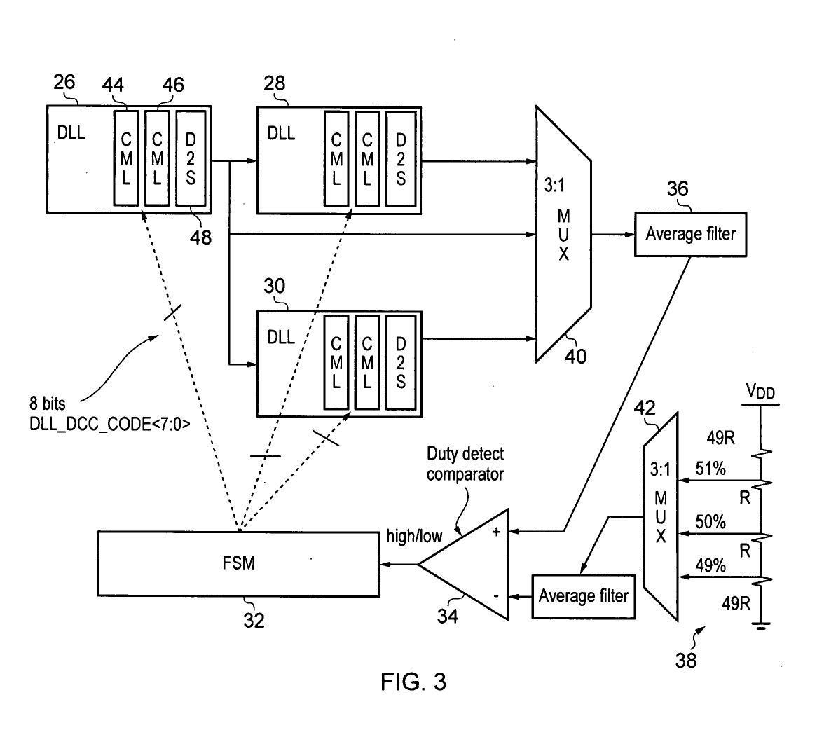

FIG. 3 schematically illustrates an example of a system incorporating duty cycle correction circuitry 26, 28, 30 operating under control of respective digital correction values produced by controller circuitry 32. Detector circuitry 34, 36, 38 serves to detect whether a digital signal (clock signal) output from the duty cycle correction circuitry 26, 28, 30 has a desired target duty cycle.

The controller circuitry 32 and the detector circuitry 34, 36, 38 is connected via a multiplexer 40 to each of the three different duty cycle correcting circuitry 26, 28, 30. Thus, the controller circuitry 32 and the detector circuitry 34, 36, 38 is shared between multiple duty cycle correction circuitry 26, 28, 30, thereby reducing the overhead associated with these duty cycle correction mechanisms. The controller circuitry 32 generates individual digital correction values which have been adjusted for the individual requirements of each of the duty cycle correction circuitry 26, 28, 30.

The detection circuitry 34, 36, 38 includes a resistor ladder 38 which may be used to provide voltages that are accurately set to be 51%, 50% and 49% of the supply voltage VDD. A multiplexer 42 is used to supply a selected one of these reference voltage levels to a comparator 34. The multiplexer 40 supplies the output clock signal from one of the duty cycle correction circuitry 26, 28, 30 to an averaging circuit 36 which integrates this clock signal value to produce a voltage level indicative of the duty cycle of that clock signal. A duty cycle accurately held at 50% will have an average voltage level of 50% of the supply voltage VDD. Similarly, a duty cycle of 49% of the high signal level should have an averaged value of 49% of VDD. The averaged values from the averaging circuitry 36 are supplied to another input of the comparator circuitry 34 where they are compared with the reference value selected from the resistor ladder 38. The output from the comparator 34 indicates whether the duty cycle of the clock signal being measured is above or below a given duty cycle value corresponding to the reference voltage level selected from the resistor ladder 38. Thus, the comparator circuitry 34 effectively provides a high/low signal to the controller circuitry 32 which may use this to adjust the digital correction values supplied in order to achieve a target duty cycle. The controller circuitry 32 may have the form of a finite state machine as will be described later below.

Each of the duty cycle correcting circuitry 26, 28, 30 illustrated in FIG. 3 includes a common mode logic stage 44 in which the duty cycle correction is applied, a further common mode logic stage 46 in which impedance adjustment is performed and a differential-to-signal stage 48 in which the differential signals processed by the common mode logic stages 44, 46 are transformed into a single signal representing the digital signal.

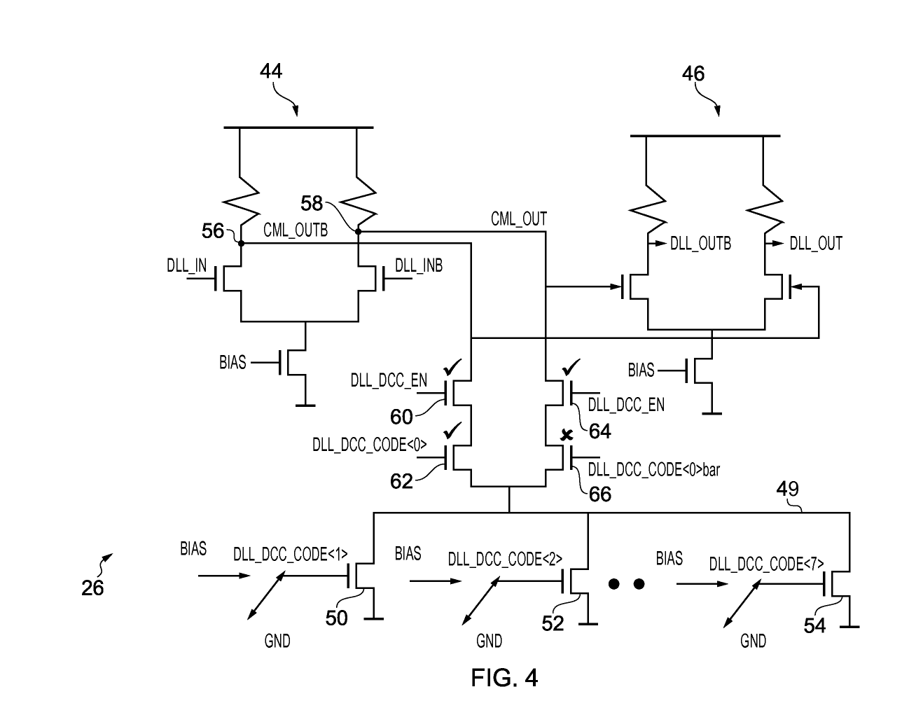

FIG. 4 schematically illustrates the duty cycle correction circuitry 26 in more detail. A common mode logic stage 44 applies duty cycle correction through the action of auxiliary current path circuitry 48 in the form of a plurality of parallel connected transistors 50, 52, 54 each controlled by a respective bit of the digital correction value. A first signal node 56 is connected to the auxiliary current path circuitry 48 via a correction enabling gate 60 and a correction direction indicating gate 62. A second signal node 58 is similarly connected to the auxiliary current path circuitry 48 via a connection enabling gate 64 and a correction direction indicating gate 66. A least significant bit of the digital correction value controls whether either gate 62 or gate 66 is in its low impedance state and accordingly whether either the first signal node 56 or the second signal node 58 is connected to the auxiliary current path circuitry 48. The correction enabling dates 60, 64 serve to either disable or enable the duty cycle correction as a whole.

The action of the auxiliary current circuitry 48 is to apply an offset to the voltage at a selected one of the first signal node 56 and the second signal node 58 with an offset magnitude that is dependent upon the digital correction value. The parallel transistors 50, 52, 54 have a binary relationship in their impedance (e.g. each of the transistors has an impedance which is a factor of two different to its neighbour), such that a desired combined parallel impedance of the auxiliary current path circuitry 48 may be selected by a corresponding value of the most significant seven bits of the eight bit digital correction value supplied by the controller circuitry 32. Thus, the offset is applied to a selected one of the first signal node 56 and the second signal node 58 depending upon the direction of duty cycle correction desired (i.e. either a decrease or an increase) and the magnitude of that offset is controlled by the most significant seven bits of the digital correction value switching to their low impedance state selected ones of the parallel transistors 50, 52, 54 to achieve an overall desired combined parallel impedance of the auxiliary current path 48.

As the digital signal is represented by the difference between the digital signals values output from the first signal node 56 and the second signal node 58, applying an offset to one of these signal nodes 56, 58 will change the times at which these signal values cross over in magnitude when driven by the signal values DLL_IN and DLL_INB that are input to the common mode logic stage 44. Thus, the digitally controlled offset applied adjusts the duty cycle of the digital signal represented by the difference of the signal values at the first signal node 56 and the second signal node 58.

The common mode logic stages 44 and 46 are in themselves inherently analog in their operation and provide a desirable degree of noise and jitter immunity. This noise and jitter immunity provided by the common mode logic stages and their differential mode of operation is combined with digital control by the use of the auxiliary current path circuitry 48 applying an offset voltage within the common mode logic stage 44 which adjusts the duty cycle without reducing the noise and jitter immunity inherently provided by the common mode logic stage.

A problem with the duty cycle correction applied to the common mode logic stage 44 is that it tends to decrease the tail current impedance of the common mode logic stage 44. This may be compensated for by the provision of the further common mode logic stage 46 which receives as its differential input signals the voltages from the first signal node 56 and the second signal node 58. The further common mode logic stage 46 has a greater tail current impedance than is achieved by the action of the common mode logic stage 44 and the auxiliary current path circuitry 48. Thus, the further common mode logic stage 46 is better able to drive the subsequent differential-to-single stage 48 resulting in better common mode noise rejection and a more symmetric input in to differential-to-signal stage 48. The further common mode logic stage 46 has high r_out of tail current, high bandwidth and high gain compared with the common mode logic stage 44. These characteristics of the further common mode logic stage 46 help in achieving less drift in the operation of the system. The further common mode logic stage 46 can be used independently of the periodic detection of duty cycle drift.

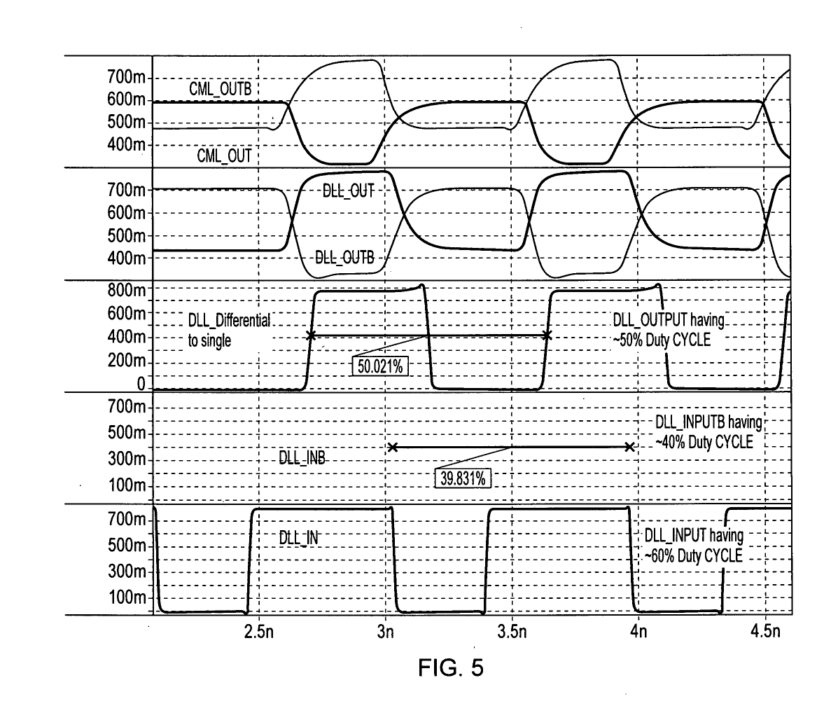

FIG. 5 is a signal diagram schematically illustrating signals arising during the operation of the circuitry of FIG. 4. In this example, the input digital signal represented by the differential signals DLL_IN and DLL_INB at the bottom of FIG. 5 has a duty cycle of 60%. The target duty cycle is 50%. The correction direction indicating gate 62 is switched to its low impedance state while the direction indicating gate 66 remains in its high impedance state. This applies the offset in voltage to the first signal node 56 as can be seen in the offset of the signal value CLM_OUTB illustrated in the top trace of FIG. 5. The effect of this offset to the voltage at the first signal node 56 is that the crossing points of the signals CLM_OUTB and CLM_OUT are adjusted such that the duty cycle now represented by those two differential signals has the target duty cycle of 50%. The further common mode logic stage 46 is switched by the differential signals output from the common mode logic stage 44 and generates outputs DLL_OUT and DLL_OUTB as illustrated in the second trace in FIG. 5. These differential signals output from the further common mode logic stage 46 represent a digital signal with a duty cycle of 50%. Accordingly, when the output from the further common mode logic stage 46 is processed by the differential-to-single stage 48 the output is as illustrated in the third trace on FIG. 5 and is a square wave with the desired target 50% duty ratio. The fourth and fifth traces in FIG. 5 illustrate the differential input signals to the common mode logic stage 44 having the 60% duty cycle in the DLL_IN signal which is corrected by the action of the duty cycle correction circuitry 26 back to the desired target 50% duty cycle.

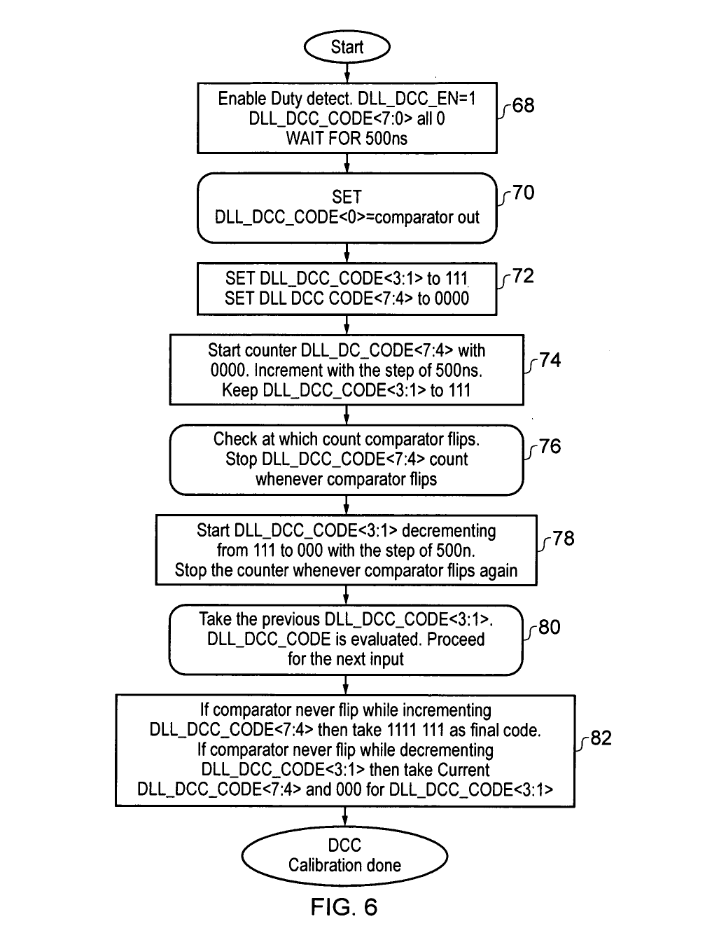

FIG. 6 is a flow diagram schematically illustrating the operation of the controller circuitry 32 in establishing an initial digital correction value. At step 68 duty cycle correction is enabled and the transistors 60 and 64 are switched to their low impedance state. Step 70 then sets an initial value for the direction of correction to be applied by setting a value of the least significant bit of the digital correction value. Step 72 sets initial bit values of the remaining bits of the digital correction value. Steps 74 and 76 then cycle through changes in the most significant bits of the correction value resulting in large step changes in the offset applied by the auxiliary current path circuitry 48. When the comparator 34 indicates a change in its output, this corresponds to the duty cycle having changed from a value on one side of the target duty cycle to a value on the other side of the target duty cycle. At this point, the most significant bits may be held fixed while steps 78 and 80 serve to adjust the least significant bits of the digital correction value used to control the auxiliary current path circuitry 48 to bring the duty cycle back to before the flipping of the comparator value output occurred by decrementing these lower resolution values until a change in comparator output is again observed. Step 82 serves to set default values for the digital correction value if the flip(s) in output from the comparator circuitry 34 does not occur as expected during the operation of the calibration process of FIG. 6.

The process illustrated in FIG. 6 is performed at the first operation of the integrated circuit 2 or following a reset of the duty cycle correction circuitry. The digital correction value obtained produces a duty cycle corresponding to the target duty cycle is stored within register 12 of the controller circuitry 8. This digital correction value can thus be directly read upon subsequent start up of the integrated circuit 2 and applied without the need for the steps of FIG. 6 to be undertaken. This reduces the settle time needed for the operation of the integrated circuit 2 upon start up.

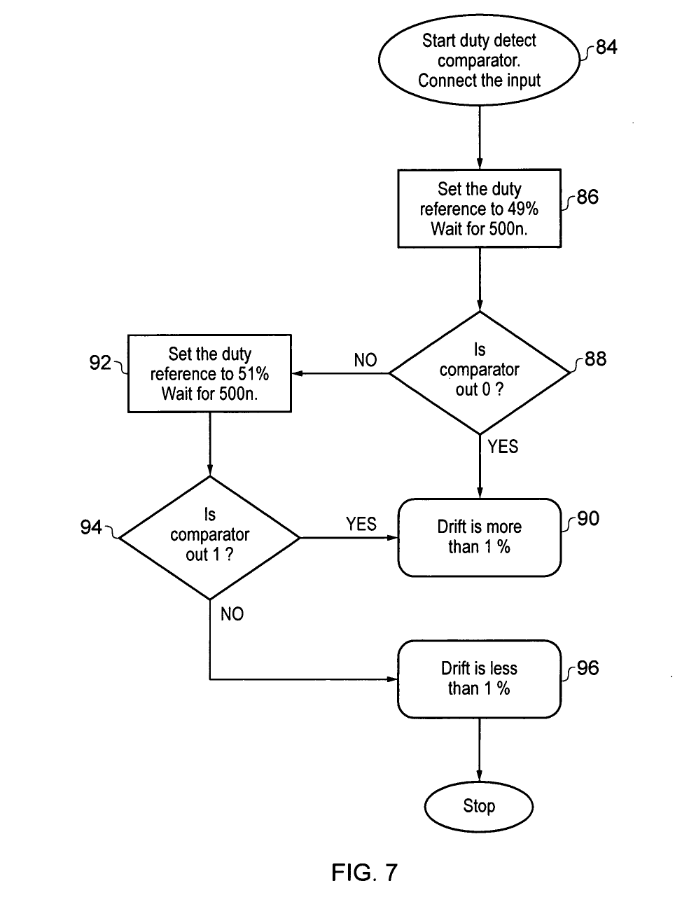

FIG. 7 is a flow diagram schematically illustrating the periodic detection of whether or not the duty cycle has drifted outside of a threshold range of duty cycles. Step 84 periodically starts up the duty cycle detection and measurement process. Step 86 sets the duty cycle reference value to 49% of the target duty cycle using the resistor ladder 38 of FIG. 3. Step 88 determines whether or not the duty cycle being output from the duty cycle correction circuitry 26, 28, 30 is less than 49%, i.e. has drifted away from the target duty cycle of 50% to below the limit of the threshold range of duty cycle of 49%. If the determination at step 88 is that the duty cycle has drifted outside of the threshold range, then processing proceeds to step 90 where the processing of FIG. 6 is repeated and a new digital correction value determined that brings the duty cycle back within the threshold range.

If the determination at step 88 is that the duty cycle has not fallen below the lower 49% limit of the threshold range of duty cycle, then processing proceeds to step 92 where the duty cycle reference is set to a value corresponding to 51%. Step 94 then determines whether or not the duty cycle is above this 51% threshold limit value. If the duty cycle is above this upper threshold limit, then processing again proceeds to step 90 where a new value of the digital correction value is determined in accordance with the processing of FIG. 6. If the determination at step 94 is that the duty cycle has not exceeded the upper threshold limit, then processing proceeds to step 96 where it is determined that any drift that has occurred is less than plus or minus 1% and no correction to the digital correction value is needed.

It will be appreciated that the example target duty cycle of 50% and the example threshold limit duty cycles of 49% and 51% are only one possibility for the values that may be employed. It may be that the target duty cycle is different from 50% in some circumstances. Furthermore, the threshold range of duty cycles about this target duty cycle may be broader or narrower than the 1% of this example. Furthermore, the threshold range need not necessarily be symmetric about the target duty cycle. All of these possibilities are encompassed within the present techniques.

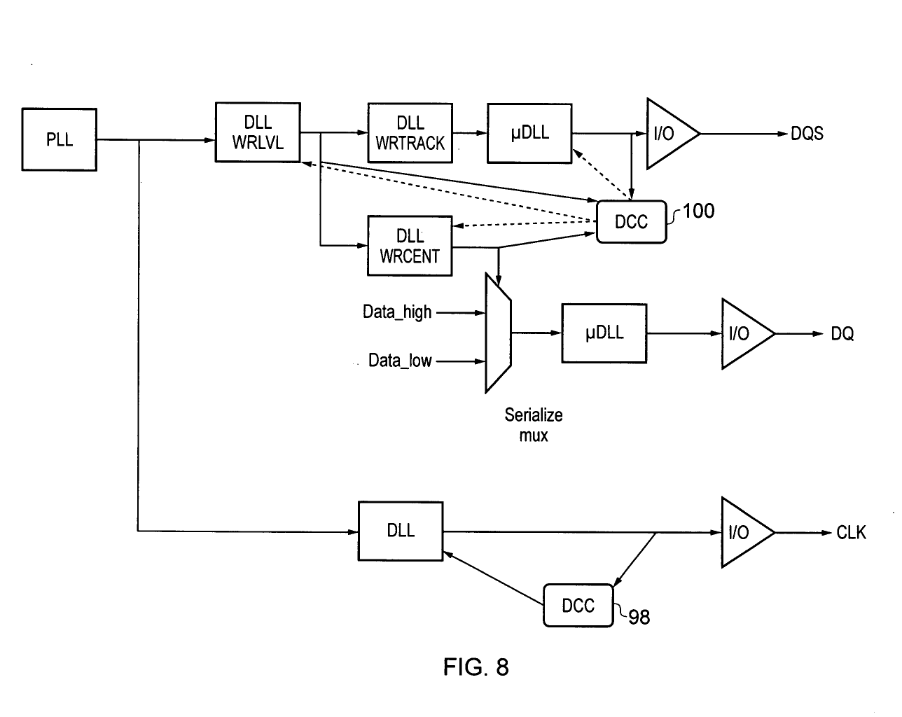

FIG. 8 schematically illustrates the use of the present techniques within DDR memory interface circuitry. The clock signal CLK is subject to duty cycle correction by duty cycle correcting circuitry 98 as discussed above. Also illustrated in FIG. 8 is duty cycle correcting circuitry 100 that acts upon the data path to control the duty cycle of the data signals DQ (e.g. DQ bits DQ0 to DQ7) and the data strobe signal DQS. Conventionally duty cycle correction is performed upon the clock signal CLK, but not the data path signals. The signals of the data path are non-clocked signals.

In order to control the data path, initial training may be performed with the input clock applied to the data path so that the duty cycle of the data path signals DQ and DQS output from the data path may be corrected. This correction/control may or may not be periodically repeated if a drift is detected in a manner similar to that described above for the clock signal. The duty cycle correction of the data path may also be performed with periodic detection of drift and further correction if needed.

FIG. 8 shows the duty cycle correcting circuitry 100 with incoming and outgoing arrows. The incoming arrows show where detecting of a duty cycle is performed. The outgoing arrows illustrate where the correcting code is applied for the particular DLL (delay locked loop) circuit concerned.

Although illustrative embodiments of the invention have been described in detail herein with reference to the accompanying drawings, it is to be understood that the invention is not limited to those precise embodiments, and that various changes and modifications can be effected therein by one skilled in the art without departing from the scope and spirit of the invention as defined by the appended claims.

1. An integrated circuit operating with a digital signal having a duty cycle, said apparatus comprising:
duty cycle correcting circuitry configured to be controlled with a digital correction value to correct said duty cycle to match a target duty cycle;
detecting circuitry configured periodically to detect if said duty cycle has drifted outside of a threshold range of duty cycles encompassing said target duty cycle; and
controller circuitry coupled to said duty cycle correcting circuitry and to said detecting circuitry and configured to change said digital correction value so as to control said duty cycle correcting circuitry to bring said duty cycle back within said threshold range if said detecting circuitry detects that said duty cycle has drifted outside of said threshold range, wherein said detecting circuit comprises:
averaging circuitry configured to average said digital signal to generate an average value indicative of said duty cycle; and
comparator circuitry configured to compare said average value with a predetermined value indicative of a given duty cycle to generate a comparison output value indicating whether said duty cycle is greater than or less than said given duty cycle, and wherein said detecting circuitry is configured to detect if said duty cycle is outside said threshold range of duty cycles by comparing said average value with respective predetermined values corresponding to limiting values of said threshold range of duty cycles.

2. An integrated circuit as claimed in claim 1, comprising
a register configured to store said digital correction value; wherein
upon starting operation of said integrated circuit after a digital correction value has been stored in said register, said controller circuitry is configured to read said digital correction value from said register for use in said controlling of said duty cycle correction circuitry.

3. An integrated circuit as claimed in claim 2, wherein said controller circuitry is configured to store said digital correction value into said register upon a first operation of said integrated circuit.

4. An integrated circuit as claimed in claim 2, wherein said controller circuitry is configured to store said digital correction value into said register upon a reset of said duty cycle correcting circuitry.

5. An integrated circuit as claimed in claim 1, wherein said digital signal is a clock signal for controlling operation of said integrated circuit.

6. An integrated circuit as claimed in claim 1, wherein said integrated circuit is one of:
a memory controller for double data rate memory; and
a double data rate memory.

7. An integrated circuit as claimed in claim 1, wherein said duty cycle correcting circuitry includes a common mode logic stage in which said digital signal is represented as a difference between two signals propagating through said common mode logic stage.

8. An integrated circuit as claimed in claim 7, wherein said duty cycle correcting circuitry is controlled by said digital correction value to generate an asymmetry in operation of said common mode logic stage with respect to different phases of said digital signal.

9. An integrated circuit as claimed in claim 8, wherein
said common mode logic stage comprises a first current path coupled to a first signal node and switched to a low impedance state when said digital signal is within a first phase and a second current path coupled to a second signal node and switched to a low impedance state when said digital signal is within a second phase; and
said duty cycle correcting circuitry comprises an auxiliary current path coupled to a selected one of said first signal node and said second signal node, impedance of said auxiliary current path being controlled by said digital correction value to provide an offset to a voltage level at said selected one of said first signal node and said second signal node.

10. An integrated circuit as claimed in claim 9, wherein one bit of said digital correction value controls said duty cycle correction circuitry to connect one of said first signal node and said second signal node to said auxiliary current path.

11. An integrated circuit as claimed in claim 9, wherein said auxiliary signal path comprises a plurality of transistors connected in parallel and each controlled to switch between a high impedance state and a low impedance state by a respective bit of said digital correction value.

12. An integrated circuit as claimed in claim 11, wherein said plurality of transistor are configured such that each has a low impedance state with an impedance value that is substantially equal to one of a sequence of impedance values of 2^{N}*X, where N is one of a sequence of incrementing integers and X is a predetermined impedance value.

13. An integrated circuit as claimed in claim 8, wherein said duty cycle correcting circuitry comprises a further common mode logic stage disposed to receive said digital signal from said common mode logic stage where said duty cycle is corrected, said further common mode logic stage having an greater tail current impedance than said common mode logic stage.

14. An integrated circuit as claimed in claim 13, wherein a differential-to-single converter stage is disposed to receive said digital signal from said further common mode logic stage and is configured to convert said digital signal from a difference between said two signals to a single digital signal.

15. An integrated circuit as claimed in claim 1, comprising a plurality of duty cycle correcting circuitry each configured to correct a duty cycle of a respective digital signal and multiplexing circuitry configured to select one of said plurality of duty cycle correcting circuitry to connect to said detecting circuitry and said controller circuitry.

16. (canceled)

17. (canceled)

18. An integrated circuit as claimed in claim 1, wherein said threshold range of duty cycles extends from 49% to 51%.

19. An integrated circuit as claimed in claim 1, wherein said integrated circuit is a memory and said digital signal is a data path signal within memory interface circuitry.

20. An integrated circuit operating with a digital signal having a duty cycle, said apparatus comprising:
duty cycle correcting means for correcting said duty cycle to match a target duty cycle under control of a digital correction value;
detecting means for periodically detecting if said duty cycle has drifted outside of a threshold range of duty cycles encompassing said target duty cycle; and
controller means, coupled to said duty cycle correcting means and to said detecting means, for changing said digital correction value so as to control said duty cycle correcting means to bring said duty cycle back within said threshold range if said detecting means detects that said duty cycle has drifted outside of said threshold range, wherein said detecting means comprises:
averaging means for averaging said digital signal to generate an average value indicative of said duty cycle; and
comparator means for comparing said average value with a predetermined value indicative of a given duty cycle to generate a comparison output value indicating whether said duty cycle is greater than or less than said given duty cycle, and wherein said detecting means is configured to detect if said duty cycle is outside said threshold range of duty cycles by comparing said average value with respective predetermined values corresponding to limiting varies of said threshold range of duty cycles.

21. A method of correcting a duty cycle of a digital signal within an integrated circuit, said method comprising the steps of:
correcting said duty cycle to match a target duty cycle duty cycle under control of a digital correction value;
periodically detecting if said duty cycle has drifted outside of a threshold range of duty cycles encompassing said target duty cycle; and
if said duty cycle has drifted outside of said threshold range, then changing said digital correction value so as to control bringing of said duty cycle back within said threshold range, wherein said step of periodically detecting comprises:
averaging said digital signal to generate an average value indicative of said duty cycle; and
comparing said average value with a predetermined value indicative of a given duty cycle to generate a comparison output value indicating whether said duty cycle is greater than or less than said given duty cycle, and wherein said step of periodically detecting circuitry detects if said duty cycle is outside said threshold range of duty cycles by comparing said average value with respective predetermined values corresponding to limiting values of said threshold range of duty cycles
